(19) United States
(12) Patent Application Publication
(10) Pub. No.: US 2023/0073302 A1
(43) Pub. Date: Mar. 9, 2023

(54) SEMICONDUCTOR STORAGE DEVICE AND CONTROLLING METHOD THEREOF

(71) Applicant: Kioxia Corporation, Tokyo (JP)

(72) Inventor: Hiroshi ITO, Yokohama (JP)

(73) Assignee: Kioxia Corporation, Tokyo (JP)

(21) Appl. No.: 17/587,961

(22) Filed: Jan. 28, 2022

(30) Foreign Application Priority Data
Sep. 3, 2021 (JP) 2021-144264

(51) Int. Cl. G11C 17/18; G11C 17/16; G11C 13/00

(52) U.S. Cl. CPC G11C 17/18; G11C 17/16; G11C 13/0069; G11C 13/004; G11C 13/0004

(57) ABSTRACT

A memory includes first and second lines. A cell-array comprises memory cells located to intersection regions between the first and second lines. A controller applies a voltage to the memory cells via the first and second lines. The cell-array comprises a first area used for reading or writing of data in a normal operation, and a second area storing predetermined data used for adjustment of the controller. The controller writes first logical data into the first area by applying a first voltage thereto and writes second logical data by applying a second voltage smaller than the first voltage, in the normal operation. The controller applies a third voltage to both first cells storing the first logical data and second cells storing the second logical data in the second area and then reads the predetermined data, after power-on and before starting the normal operation.

### CROSS REFERENCE TO RELATED APPLICATIONS

This application is based upon and claims the benefit of priority from the prior Japanese Patent Application No. 2021-144264, filed on Sep. 3, 2021, the entire contents of which are incorporated herein by reference.

### FIELD

The embodiments of the present invention relate to a semiconductor storage device and a controlling method thereof.

### BACKGROUND

An SCM (Storage Class Memory) based on a memory such as a PCM (Phase Change Memory) or a ReRAM (Resistive Random Access Memory) is recently developed. While the PCM and the ReRAM are non-volatile memories, many thereof have a data retention period shorter than the product life and are difficult to store data for a long period. In such a case, a refresh operation of reading data before being lost and rewriting the data is required. Data of trimming information or redundancy information needs to be retained during the product life without the need for refresh. For this purpose, it is necessary to mount OTP (One-Time Programming) based on non-volatile storage elements different from memory cells.

An example of the storage elements used in the OTP is an electrically programmable fuse element (eFuse). The eFuse is a generic term for elements that store therein information by disconnecting a line by a current, short-circuiting an insulating film by a high voltage, or electrically irreversibly changing the state of an element on a semiconductor integrated circuit. The eFuse is larger in the element size than a memory cell in a PCM or a ReRAM and requires a larger current and a higher voltage, so that a selection device also needs a transistor of a larger size, a transistor for high-voltage protection, or the like, which leads to an increase in the area on a chip occupied by the OTP.

### BRIEF DESCRIPTION OF THE DRAWINGS

FIG. 1 is a diagram illustrating a configuration example of a non-volatile semiconductor storage device according to a first embodiment;

FIG. 2 is a schematic diagram illustrating a configuration example of a memory cell and a peripheral part;

FIG. 3 is a graph illustrating voltage-time curves in the set operation and the reset operation;

FIG. 4 is a diagram illustrating a state from the inspection process to the normal operation in a normal area and an OTP area in the memory cell array;

FIG. 5A is a flowchart from the inspection process of the memory cell array to the shipment thereof;

FIG. 5B is a flowchart from the shipment to the normal operation of the memory cell array; and

FIG. 6 is a schematic diagram illustrating a configuration example of the semiconductor storage device according to a second embodiment.

### DETAILED DESCRIPTION

Embodiments will now be explained with reference to the accompanying drawings. The present invention is not limited to the embodiments. In the present specification and the drawings, elements identical to those described in the foregoing drawings are denoted by like reference characters and detailed explanations thereof are omitted as appropriate.

A semiconductor storage device according to the present embodiment comprises a plurality of first lines and a plurality of second lines. A memory cell array comprises a plurality of memory cells located to correspond to intersection regions between the first lines and the second lines. A control circuit is configured to apply a voltage to the memory cells via the first and second lines. The memory cell array comprises a first memory area used for reading or writing of data in a normal operation, and a second memory area storing predetermined data used for adjustment of the control circuit. The control circuit writes first logical data into the first memory area by applying a first voltage thereto and writes second logical data by applying a second voltage smaller in an absolute value than the first voltage, in the normal operation. The control circuit applies a third voltage to both first memory cells storing the first logical data and second memory cells storing the second logical data in the second memory area and then reads the predetermined data, after power-on and before starting the normal operation.

### First Embodiment

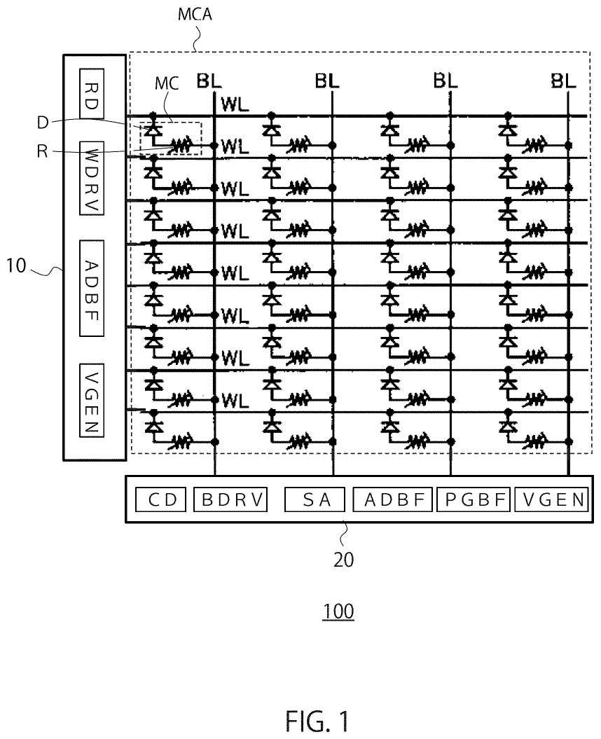

FIG. 1 is a diagram illustrating a configuration example of a non-volatile semiconductor storage device 100 according to a first embodiment. The non-volatile semiconductor storage device 100 (hereinafter, simply “storage device 100”) includes a memory cell array MCA, and control circuits 10 and 20 as peripheral circuits.

The memory cell array MCA is configured to include a plurality of memory cells MC storing data therein to be arranged two-dimensionally or three-dimensionally. The memory cell array MCA includes a plurality of word lines WL and a plurality of bit lines BL. The word lines WL and the bit lines BL intersect with each other and are, for example, substantially orthogonal to each other in a planar layout. The memory cells MC are located to correspond to intersection regions between the word lines WL and the bit lines BL and are connected between the word lines WL and the bit lines BL, respectively. Therefore, the memory cell array MCA is a so-called cross-point memory cell array. The number of the word lines WL, the number of the bit lines BL, and the number of the memory cells MC are not particularly limited.

Each of the memory cells MC can be a resistance-change memory cell including a resistance change element R including a first electrode 11, a second electrode 12, and a resistance change film RE, and a selection element (a selector) having non-linear current characteristics. The selection element can be, for example, a diode D. The resistance change element R and the diode D are connected in series between one of the bit lines BL and an associated one of the word lines WL. The diode D is placed to electrically access (initialize/write/read) a selected cell. The diode D is provided to prevent a sneak current at the time of an access to a selected cell. One end of the resistance change element R is connected to the associated bit line BL and the other end of the resistance change element R is connected to one end (an anode) of the diode D. The other end (a cathode) of the diode D is connected to the associated word line WL. In each of the memory cells MC, the diode D may be connected in the opposite direction. The resistance change element R and the diode D may be arranged in the opposite relation in each of the memory cells MC. Each of the memory cells MC may include a two-terminal switching unit other than the diode D as the selection element. The two-terminal switching unit may have following characteristics. For example, the two-terminal switching unit is in a high resistance state, for example, an electrically non-conductive state when the voltage applied between two terminals is equal to or lower than a threshold while the two-terminal switching unit changes to a low resistance state, for example, an electrically conductive state when the voltage applied between the two terminals exceeds the threshold. In an ON state, the two-terminal switching unit keeps the ON state when a current equal to or higher than a holding current value continues to pass. The switching unit may have this function regardless of the polarity of the voltage.

For example, in a case in which the memory cells MC are PCMs, when a predetermined set voltage Vset is applied to the both ends of a memory cell MC for a certain length of time in the forward direction of the diode D, the resistance change element R is crystallized at a temperature lower than the melting point and transitions from a high resistance state to a low resistance state (a set operation). For example, when a reset voltage Vreset higher than the set voltage Vset is applied to the both ends of a memory cell MC for a short time in the forward direction of the diode D, the resistance change element R is brought to an amorphous state and transitions from the low resistance state to the high resistance state (a reset operation). In this way, the phase of the phase change film of the resistance change element R transitions when a current is passed through a memory cell MC, whereby the resistance change element R is brought to the low resistance state (a set state) or the high resistance state (a reset state). This enables the memory cell MC to store logical data as described above. There are also a case in which a transistor is used instead of the diode D as the selector and a case in which the selector itself is omitted. The memory cells MC are not limited to the PCMs.

The memory cells MC immediately after being manufactured cannot pass a current necessary for being brought to a set state or a reset state with voltages used in a normal operation because an insulating film (not illustrated) located on a current path, or the like becomes an obstacle. Therefore, initialization processing is performed in an inspection process after manufacturing, in order to enable each of the memory cells MC to transition to the set state and the reset state, that is, to be brought to a state where the resistance value can be electrically controlled. The initialization processing is processing to pass a current through the memory cells MC by applying an initialization voltage larger in the absolute value than the voltages used in the normal operation to the memory cells MC with a voltage pulse having a predetermined time width, and to enable data to be written into the memory cells MC in the normal operation. The normal operation is an operation of writing, reading, into/from memory cells in a user area. The initialization processing is performed in the inspection process before a first normal operation.

The control circuits 10 and 20 control the memory cell array MCA. The control circuit 10 includes a row decoder RD, a word line driver WDRV, an address buffer ADBF, a voltage generation circuit VGEN, and the like. The control circuit 20 includes a column decoder CD, a bit line driver BDRV, a sense amplifier SA, an address buffer ADBF, a page buffer PGBF, a voltage generation circuit VGEN, and the like.

The address buffers ADBF receive an address signal for a word line WL or a bit line BL to be selected at the time of initialization/reading/writing/ from outside and temporarily retain the address signal. The address buffers ADBF supply the address signal to the row decoder RD or the column decoder CD.

The row decoder RD decodes the address signal and selects a certain word line WL from among the word lines WL according to the address signal. The word line driver WDRV applies a predetermined voltage to the selected word line WL via the row decoder RD to enable an operation of initialization/reading/writing.

The column decoder CD decodes the address signal and selects a bit line BL according to the address signal. The bit line driver BDRV applies a predetermined voltage to the selected bit line BL to enable an operation of initialization/reading/writing. The sense amplifier SA detects data read from the selected bit line BL and transfers the data to the page buffer PGBF. The page buffer PGBF temporarily retains (latches) data to be written into the selected bit line BL or data read from the selected bit line BL.

The voltage generation circuits VGEN in the control circuits 10 and 20 are step-up circuits or step-down circuits that generate various voltages to be applied to the selected word line WL and the selected bit line BL from external power.

With this configuration, the control circuits 10 and 20 can select a certain word line WL and a certain bit line BL and apply various voltages thereto. As a result, an operation of initialization/reading/writing can be performed to a memory cell MC (a selected cell) connected between the selected word line WL and the selected bit line BL.

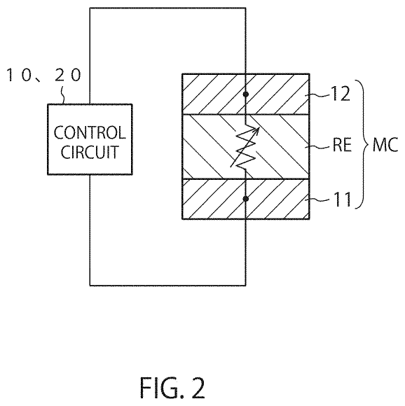

FIG. 2 is a schematic diagram illustrating a configuration example of a memory cell and a peripheral part. Each of the memory cells MC includes the first electrode 11, the second electrode 12, the resistance change film RE, and the control circuits 10 and 20. Illustrations of the diode D are omitted in FIG. 2.

The resistance change film RE is connected between the first electrode 11 and the second electrode 12 and can reversibly change between a low resistance state and a high resistance state in the normal operation after initialization. Drivers of the control circuits 10 and 20 can apply a voltage to the resistance change film RE located between the first electrode 11 and the second electrode 12 via the electrodes 11 and 12. The control circuits 10 and 20 can change a voltage difference between the first electrode 11 and the second electrode 12 by controlling the drivers.

The location relation between the first and second electrodes 11 and 12 is not particularly limited and may be inverted. The first electrode 11, the second electrode 12, and the resistance change film RE can be single layer films, respectively, or may be a stacked layer film including a plurality of layers.

For example, a metal such as Ni, Pt, Au, Ag, Ru, Ir, Co, Ti, Al, Rh, Nb, or W, doped polysilicon, or a silicide including any of these metals and doped polysilicon is used as the first and second electrodes 11 and 12. For example, TiAIN, SrRuO₃, RuN, TiN, TaN, LaNiOx, PtlrOx, PtRhOx, TaAlN, InSnOx, or the like may be used as the first and second electrodes 11 and 12.

For example, a phase-change material such as Ge—Sb—Te chalcogenide compounds (GST) including Ge₂Sb₂Te₅ is used as the resistance change film RE. The resistance change film RE can reversibly change to at least two resistance states (a high resistance state and a low resistance state) in the normal operation.

One of the two resistance states of the resistance change film RE is referred to as “low resistance state (LRS)” and a state higher in the resistance than the LRS is referred to as “high resistance state (HRS)”. As described above, the high resistance state HRS is also referred to as “reset state” and the low resistance state LRS is also referred to as “set state”.

In a pre-initialization state before the initialization, the resistance change film RE is in a higher resistance state than the high resistance state HRS. The resistance change film RE in the pre-initialization state is enabled to perform a normal operation by the initialization processing.

The control circuits 10 and 20 control a difference between the voltages applied to the first and second electrodes 11 and 12 via the drivers at the time of setting/resetting in the normal operation.

Setting is an operation to change the resistance change film RE from the high resistance state (reset state) HRS to the low resistance state (set state) LRS. Resetting is an operation to change the resistance change film RE from the low resistance state (set state) LRS to the high resistance state (reset state) HRS. A set voltage is a voltage difference required to bring the resistance change film RE to the low resistance state LRS, and a reset voltage is a voltage difference required to bring the resistance change film RE to the high resistance state HRS.

A control circuit 14 controls following two reversible operations at the time of setting/resetting in the normal operation. The set operation and the reset operation for memory cells in the normal operation are explained below.

### (Set Operation: Write “0”)

For example, when the low resistance state LRS of the resistance change film RE is assumed to be a state of logical data “0”, the set operation means writing of “0”. This set operation is reversible in the normal operation. “Being reversible” in this case means that the resistance change film RE can be returned to the reset state again after the set operation is performed.

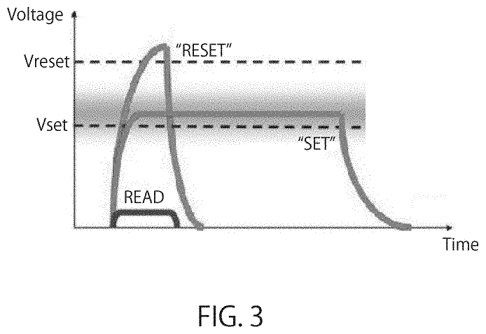

FIG. 3 is a graph illustrating voltage-time curves in the set operation and the reset operation.

In the set operation, the control circuits 10 and 20 apply a voltage V1 to the first electrode 11 and apply a voltage V2 smaller than the voltage V1 to the second electrode 12. The maximum value of a voltage difference between the two voltages V1 and V2 is the set voltage Vset (=V1−V2).

The resistance change film RE is in the high resistance state HRS before the set voltage Vset is applied to the resistance change film RE. Accordingly, the current flowing in the resistance change film RE is small at a time when the voltage difference starts being applied to the resistance change film RE. However, when the voltage difference of the resistance change film RE is thereafter caused to be the set voltage Vset for a predetermined time, the resistance change film RE is crystalized and changes to the low resistance state LRS. Therefore, after the set voltage Vset is applied to the resistance change film RE, the current flowing in the resistance change film RE becomes larger than that before the set voltage Vset is applied to the resistance change film RE. In this way, in the normal operation, the logical data “0” can be written into a memory cell MC by application of the set voltage Vset to the memory cell MC for the predetermined time by the drivers WDRV and BDRV.

### (Reset Operation: Write “1”)

For example, when the high resistance state of the resistance change film RE is assumed to be a state of logical data “1”, the reset operation means writing of “1”. This reset operation is reversible in the normal operation. “Being reversible” in this case means that the resistance change film RE can be returned to the set state again after the reset operation is performed.

In the reset operation, the control circuits 10 and 20 apply a voltage V1 to the first electrode 11 and a voltage V2 smaller than the voltage V1 to the second electrode 12. The maximum value of a voltage difference between the two voltages V1 and V2 is the reset voltage Vreset (=V1−V2). The reset voltage Vreset is, for example, a voltage larger in the absolute value than the set voltage Vset described above.

The resistance change film RE is in the low resistance state LRS before the reset voltage Vreset is applied to the resistance change film RE. Accordingly, the current flowing in the resistance change film RE is large at a time when the voltage difference starts being applied to the resistance change film RE. However, when the voltage difference of the resistance change film RE is thereafter caused to be the reset voltage Vreset for a short time (in a pulsed manner), the resistance change film RE changes to the high resistance state HRS. Therefore, after the reset voltage Vreset is applied to the resistance change film RE, the current flowing in the resistance change film RE becomes smaller than that before the reset voltage Vreset is applied to the resistance change film RE. In this way, in the normal operation, the logical data “1” can be written into a memory cell MC by application of the reset voltage Vreset in a pulsed manner to the memory cell MC by the drivers WDRV and BDRV after the set operation.

### (Initialization Processing)

Meanwhile, the resistance change film RE immediately after being manufactured is in a higher resistance state than the resistance change film RE in the normal operation. Therefore, the memory cells MC in the pre-initialization state do not operate on voltages used in the normal operation. Accordingly, the drivers WDRV and BDRV apply an initialization voltage Vint higher in the absolute value than the set voltage Vset and the reset voltage Vreset used in the normal operation to the memory cells MC in the user area as the initialization operation. With application of the initialization voltage Vint to the resistance change film RE of the memory cells MC, the resistance change film RE is brought to a state that can be controlled to the set state and the reset state in the normal operation.

This initialization processing is irreversible processing and the memory cells MC can continuously perform the reversible normal operation after the initialization processing is once performed. That is, with the initialization processing performed in the inspection process after the memory cells MC are manufactured, the memory cells MC can repeatedly perform the normal operation such as data reading, data writing, after shipment, without performing the initialization processing any more.

In the storage device 100, manufactured semiconductor elements have characteristic variation in analog circuits and the like of the control circuits 10 and 20. To precisely control the voltage, the current, and the time, a circuit configuration that enables correction or adjustment of influences of the characteristic variation needs to be provided, and data (trimming information) for adjustment needs to be determined and recorded in the inspection process.

Further, defects occur in the memory cells with a certain probability. It is difficult to zero the number of defective cells in the memory cell array. A redundancy mechanism is indispensable, in which auxiliary memory cells are prepared and the auxiliary memory cells are accessed when a memory area including defective cells is accessed.

It is necessary to detect defective cells in the inspection process and store the addresses thereof as redundancy information. Unique identification information (chip ID) is generally written into each memory chip to enable the history of manufacturing and inspection to be traced. Such information needs to be retained during the product life time with a high reliability and in a non-volatile manner and OTP therefor is required.

An eFuse can be used as the OTP. However, an eFuse has a large size and interferes with downscaling of the storage device 100.

Use of a part of the memory cell array MCA as the OTP is considered. However, since a resistance change memory such as a PCM needs the refresh operation as described above, a part of the memory cell array MCA cannot be used as the OTP.

To solve this problem, the storage device 100 according to the present embodiment stores data of trimming information and redundancy information in the memory cells MC in the pre-initialization state and the memory cells MC in the set state after initialization in the memory cell array MCA.

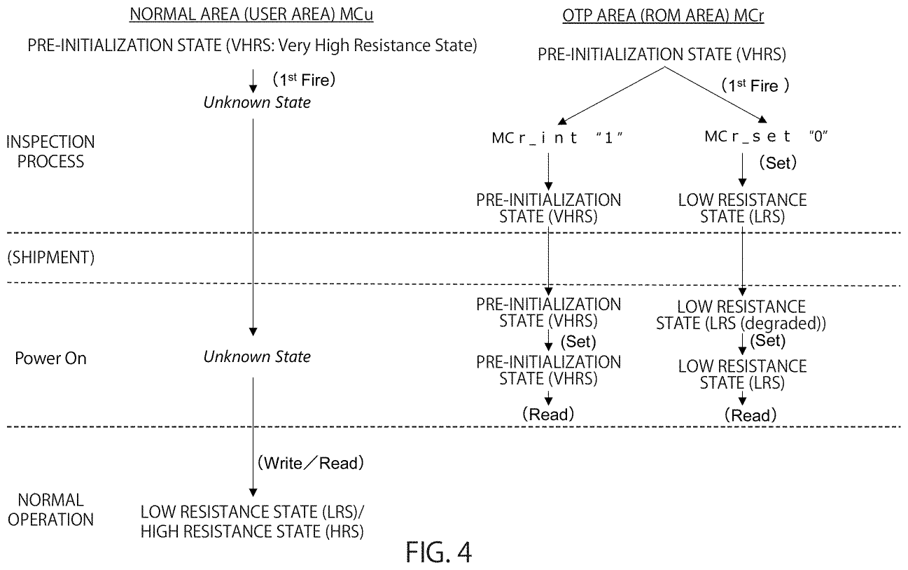

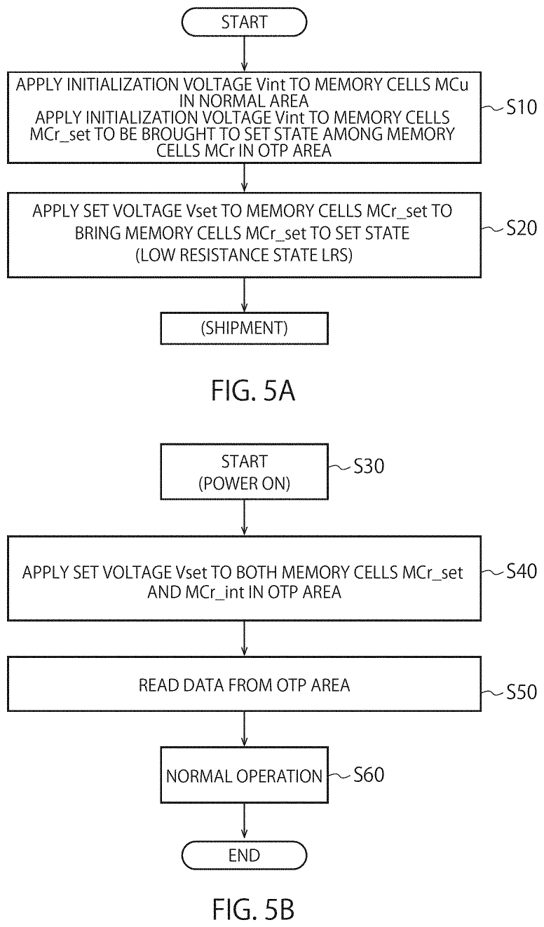

FIG. 4 is a diagram illustrating a state from the inspection process to the normal operation in a normal area (a user area) and an OTP area (a ROM area) in the memory cell array MCA. FIG. 5A is a flowchart from the inspection process of the memory cell array MCA to the shipment thereof. FIG. 5B is a flowchart from the shipment to the normal operation of the memory cell array MCA. The normal area is a memory area to be used in reading, writing of data in the normal operation. The OTP area is a memory area in which predetermined data such as the trimming information and the redundancy information to be used for adjustment of electrical characteristics (the output voltage, and the like) of analog circuits such as the reference voltage generation circuit is stored.

For sake of convenience, memory cells in the normal area (the user area) in the memory cell array MCA are referred to as MCu, and memory cells in the OTP area (the ROM area) are referred to as MCr. Memory cells in the set state (the low resistance state LRS) among the memory cells MCr are referred to as MCr_set and memory cells in the pre-initialization state are referred to as MCr_int.

First, the initialization processing is performed in the inspection process when the storage device 100 is completed. Before the initialization, the resistance change film RE of the memory cells MCu and MCr in the normal area and the OTP area has a too high pre-initialization resistance state VHRS (Very High Resistance State) to operate on the voltages used in the normal operation. That is, almost all memory cells MC in the memory cell array MCA are in the pre-initialization state.

Therefore, in the initialization processing, the drivers of the control circuits 10 and 20 apply the initialization voltage Vint to all the memory cells MCu in the normal area (the user area) in the memory cell array MCA (S10: first fire), as shown in FIG. 5A. Accordingly, the memory cells MCu in the normal area are initialized and data is enabled to be written thereinto in the normal operation. Since data writing is not performed immediately after the initialization processing, whether the memory cells MCu are in the state of data “0” or “1” is unknown (an indeterminate state).

At Step S10, the drivers of the control circuits 10 and 20 apply the initialization voltage Vint to the memory cells MCr_set to be brought to the set state (the low resistance state LRS) among the memory cells MCr in the OTP area (the ROM area) (S10: first fire). Accordingly, the memory cells MCr_set to be brought to the set state among the memory cells MCr are initialized and data is enabled to be written thereinto with voltages used in the normal operation. Timings of application of the initialization voltage Vint to the memory cells MCu and the memory cells MCr_set are not particularly limited, and the application can be simultaneously performed to the memory cells MCu and the memory cells MCr_set or can be performed in turns (sequentially) according to addresses.

The initialization voltage Vint is not applied to memory cells other than the memory cells MCr_set into which the set state is to be written among the memory cells MCr. Therefore, the memory cells other than the memory cells MCr_set among the memory cells MCr remain in the pre-initialization state and maintain the pre-initialization resistance state VHRS. Therefore, the memory cells other than the memory cells MCr_set among the memory cells MCr are referred to as MCr_int as illustrated in FIG. 4.

Next, the drivers of the control circuits 10 and 20 apply the set voltage Vset to the memory cells MCr_set to bring the memory cells MCr_set to the set state (the low resistance state LRS) (S20). Accordingly, the memory cells MCr_set are brought to the set state (the low resistance state LRS) that is lower in the resistance than the reset state. Meanwhile, the memory cells MCr_int are kept in the pre-initialization state having the pre-initialization resistance state VHRS higher than that of the reset state. Therefore, a resistance difference between the memory cells MCr_set and the memory cells MCr_int is larger than a resistance difference between the memory cells MCu_set in the set state and the memory cells MCu_reset in the reset state in the normal area. Although not initialized, the memory cells MCr_int can function as memory cells that have previously stored therein the logical data “1” of the reset state. Therefore, the control circuits 10 and 20 can read the logical data “0” or “1” from the memory cells MCr_set or MCr_int.

That is, by writing only the data “0” (the set state) of the trimming information or the redundancy information into the OTP area, the memory cells MCr_set brought to the set state and the other memory cells MCr_int in the pre-initialization state can store the trimming information or the redundancy information therein. The trimming information or the redundancy information stored in the memory cells MCr_set and MCr_int is only for reading and is not rewritten. That is, the OTP area is used as the ROM area. Therefore, after writing of the set state, the memory cells MCr_set and MCr_int become targets for a read operation of the trimming information or the redundancy information at the time of power-on or the like. However, the memory cells MCr_set and MCr_int do not become targets for an access in the normal operation.

After this inspection process is performed, the storage device 100 is, for example, shipped. While voltages (for example, the set voltage Vset and the reset voltage Vreset) in the normal operation are applied to the memory cells MCu and MCr after the inspection process, the initialization voltage Vint larger in the absolute value than the voltages in the normal operation is not applied thereto.

Next, the storage device 100 is powered-on on the user side (S30), as shown in FIG. 5B. At this time, data in the memory cells MCu in the normal area are in an indeterminate state.

Meanwhile, the drivers of the control circuits 10 and 20 read the trimming information or the redundancy information from the memory cells MCr in the OTP area. At this time, the drivers read data from the OTP area after performing the set operation on the memory cells MCr in the whole OTP area.

The set operation on the memory cells MCr before reading is performed by application of the set voltage Vset to both the memory cells MCr_set and MCr_int in the OTP area (S40). Since the memory cells MCr_set have been initialized and enabled to be operated with voltages in the normal operation at this time, the set state is written thereinto. Meanwhile, the memory cells MCr_int are in the pre-initialization state and data cannot be written thereinto with voltages in the normal operation. That is, even when the set voltage Vset lower than the initialization voltage Vint is applied to the memory cells MCr_int, the memory cells MCr_int are not brought to the set state and keep the pre-initialization state. Therefore, by the set operation on the memory cells MCr in the whole OTP area, the set state can be selectively written only into the memory cells MCr_set. If data in the memory cells MCr_set is degraded, the data can be recovered by selectively (in a self-aligned manner) writing the set state into the memory cells MCr_set.

At this time, the voltage applied to the memory cells MCr_set in the OTP area can be the set voltage Vset or may be a voltage lower in the absolute value than the set voltage Vset. That is, a voltage as high as the set voltage Vset does not always need to be applied and a voltage lower in the absolute value than the set voltage Vset may be applied as long as the voltage can recover degradation of the set state of the memory cells MCr_set. This can reduce electrical stress on the memory cells MCu in the normal area or other memory cells MCr in the OTP area and can suppress disturbance to other memory cells.

Next, the control circuits 10 and 20 read data from the OTP area (S50). Accordingly, accurate trimming information or redundancy information can be read from the memory cells MCr. The control circuits 10 and 20 perform setting such as adjustment of the electrical characteristics of analog circuits or replacement of defective cells in accordance with the read trimming information or redundancy information.

Thereafter, the storage device 100 enters into the normal operation and the normal operation is performed in accordance with an access of a user (S60). In the normal operation, the user can access the memory cells MCu in the normal area and can freely write, read.

At this time, the OTP area does not become a target for the access and retains the trimming information or the redundancy information. There is a case in which the set state of the memory cells MCr_set in the OTP area is degraded due to passage of time or disturbance in the normal operation. However, at the time of next power-on, the drivers of the control circuits 10 and 20 write the set state into the memory cells MCr in the whole OTP area and then read the trimming information or the redundancy information. The memory cells MCr_int are still in the pre-initialization state at this time and the set state is written only into the memory cells MCr_set. Therefore, no problems occur even when the data of the set state in the memory cells MCr_set is degraded.

As described above, according to the present embodiment, the drivers WDRV and BDRV apply the initialization voltage Vint to the memory cells MCr_set designed to store the set state in the OTP area and do not apply the initialization voltage Vint to the memory cells MCr_int designed to store the reset state in the initialization processing. Accordingly, the memory cells MCr_set in the OTP area are initialized and store the set state. The memory cells MCr_int are not initialized and keep the pre-initialization state. Since being in the pre-initialization state having a higher resistance than that of the reset state (the high resistance state HRS), the memory cells MCr_int function as memory cells that store the reset state. Therefore, with only writing of the set state into the memory cells MCr_set by the control circuits 10 and 20, a state equivalent to writing of predetermined trimming information or redundancy information into the OTP area is obtained.

The control circuits 10 and 20 apply the set voltage Vset to both the memory cells MCr_int in the pre-initialization state and the memory cells MCr_set in the set state in the OTP area after power-on and before the normal operation is started. The set voltage Vset is smaller in the absolute value than the initialization voltage Vint. Therefore, the set state can be written again into the memory cells MCr_set with the memory cells MCr_int kept in the pre-initialization state. Accordingly, even when the storage device 100 is left unused for a long time and the set state of the memory cells MCr_set is degraded, the set state of the memory cells MCr_set can be restored.

Thereafter, the control circuits 10 and 20 read predetermined data such as the trimming information or the redundancy information from the OTP area. The predetermined trimming information or redundancy information can be read by reading data “1” from the memory cells MCr_int and reading data “0” from the memory cells MCr_set.

The memory cells MCr_int can maintain the pre-initialization state as long as a voltage not exceeding the initialization voltage Vint in the absolute value is applied thereto even when data patrol or a refresh operation is performed. Therefore, the present embodiment can be applied to any device that performs a refresh operation.

### Second Embodiment

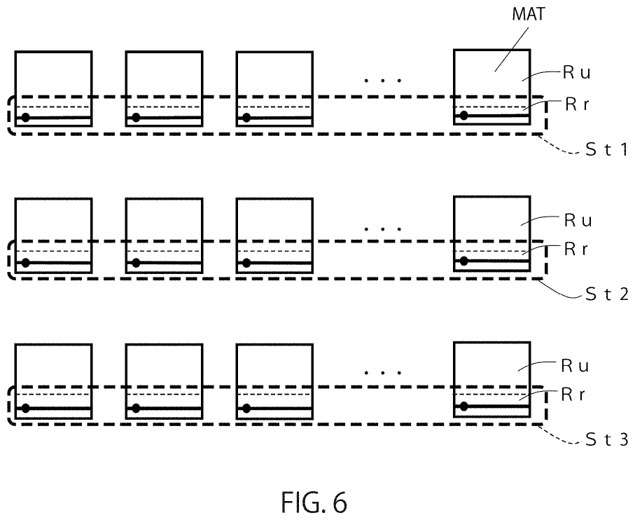

FIG. 6 is a schematic diagram illustrating a configuration example of the semiconductor storage device 100 according to a second embodiment. In the second embodiment, redundancy is provided for predetermined data such as the trimming information or the redundancy information and same predetermined data is stored in a plurality of places in the OTP area.

For example, the memory cell array MCA is separated into units called “mats” each including a plurality of memory cells MC. A normal area Ru and an OTP area Rr are set in each of the mats. A set St1 of a plurality of mats has predetermined data such as the trimming information or the redundancy information stored therein. A set St2 of a plurality of mats has the same predetermined data such as the trimming information or the redundancy information stored therein. Further, a set St3 of a plurality of mats has the same predetermined data such as the trimming information or the redundancy information stored therein. In this way, the sets Sti to St3 of mats have the same predetermined data stored therein, whereby redundancy of the trimming information or the redundancy information is maintained.

One piece of trimming information, redundancy information, or the like is also stored in a distributed manner in a plurality of mats. One piece of trimming information, redundancy information, or the like can be obtained by reading data from the OTP area of the mats.

Due to this provision of redundancy for predetermined data, accurate trimming information, redundancy information, or the like can be obtained even if data of a part of the OTP area is corrupted. For example, even when data in the set St2 among the sets St1 to St3 of mats is corrupted, accurate trimming information, redundancy information, or the like can be obtained from the data in two sets St1 and St3. At this time, accuracy of data may be determined by a rule of majority. Data from the two sets St1 and St3 relative to data from one set St2 is determined to be accurate. The number of sets of mats that have same data stored therein may be two, or may be four or more. It is preferable that the number of sets of mats is an odd number when accuracy of data is determined by a rule of majority.

The OTP area is only accessed for writing of the set state and reading of the trimming information, the redundancy information, or the like at the time of power-on and is not accessed in the normal operation. Therefore, the memory cells MCr in the OTP area is less likely to be degraded compared to the memory cells MCu in the normal area. However, while not accessed, the memory cells MCr in the OTP area have a possibility of being degraded under disturbance from adjacent memory cells or indirect disturbance from a selected word line or a selected bit line. Therefore, provision of redundancy for the trimming information, the redundancy information, or the like can ensure a proper operation of the storage device 100 in the normal operation.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor storage device comprising:
a plurality of first lines;
a plurality of second lines intersecting with the first lines;
a memory cell array comprising a plurality of memory cells located to correspond to intersection regions between the first lines and the second lines; and
a control circuit configured to apply a voltage to the memory cells via the first and second lines, wherein
the memory cell array comprises a first memory area used for reading or writing of data in a normal operation, and a second memory area storing predetermined data used for adjustment of the control circuit,
the control circuit writes first logical data into the first memory area by applying a first voltage thereto and writes second logical data by applying a second voltage smaller in an absolute value than the first voltage, in the normal operation, and
the control circuit applies a third voltage to both first memory cells storing the first logical data and second memory cells storing the second logical data in the second memory area and then reads the predetermined data, after power-on and before starting the normal operation.

2. The device of claim 1, wherein
the control circuit applies a fourth voltage larger in an absolute value than the first and second voltages to the memory cells in the first memory area before first one among the, and
the control circuit applies the fourth voltage to the second memory cells storing the second logical data in the second memory area and does not apply the fourth voltage to the first memory cells storing the first logical data in the second memory area, before the first one among the normal operation.

3. The device of claim 1, wherein the third voltage has a value equivalent to the second voltage.

4. The device of claim 1, wherein the third voltage is a voltage smaller in an absolute value than the second voltage.

5. The device of claim 1, wherein the second memory area comprises a plurality of regions each of which stores the predetermined data.

6. The device of claim 1, wherein the control circuit does not access the second memory area for data writing, data reading in the normal operation.

7. The device of claim 1, wherein the memory cell is a resistance-change memory cell.

8. The device of claim 1, wherein each of the memory cells includes a resistance change element and a selection element connected in series between one of the first lines and one of the second lines, the selection element having non-linear current characteristics.

9. A controlling method of a semiconductor storage device comprising a plurality of first lines, a plurality of second lines intersecting with the first lines, a memory cell array comprising a plurality of memory cells located to correspond to intersection regions between the first lines and the second lines, and a control circuit configured to apply a voltage to the memory cells via the first and second lines,
the memory cell array comprising a first memory area used for reading or writing of data in a normal operation, and a second memory area storing predetermined data used for adjustment of the control circuit,
the method comprising:
powering on the semiconductor storage device;
applying a third voltage to both first memory cells storing first logical data and second memory cells storing second logical data in the second memory area;
reading the predetermined data from the second memory area; and
starting the normal operation to write first logical data into the first memory area by applying a first voltage thereto and write second logical data by applying a second voltage smaller in an absolute value than the first voltage.

10. The method of claim 9, comprising:
before the powering on,
applying a fourth voltage larger in an absolute value than the first and second voltages to the memory cells in the first memory area; and
applying the fourth voltage to the second memory cells storing the second logical data in the second memory area, and not applying the fourth voltage to the first memory cells storing the first logical data in the second memory area.

11. The method of claim 9, wherein the third voltage has a value equivalent to the second voltage.

12. The method of claim 9, wherein the third voltage is a voltage smaller in an absolute value than the second voltage.

13. The method of claim 9, wherein
the second memory area comprises a plurality of regions each of which stores the predetermined data, and
the method further comprises determining the predetermined data based on data read from the regions.

14. The method of claim 9, wherein the control circuit does not access the second memory area for data writing, data reading in the normal operation.

15. The method of claim 9, wherein the memory cell is a resistance-change memory cell.
